(19) United States
(12) Patent Application Publication
(10) Pub. No.: US 2007/0012355 A1
(43) Pub. Date: Jan. 18, 2007

(54) Nanostructured material comprising semiconductor nanocrystal complexes for use in solar cell and method of making a solar cell comprising nanostructured material

(76) Inventors: Michael LoCascio, Clifton Park, NY (US); Margaret Hines, Troy, NY (US)

Correspondence Address: KENYON & KENYON LLP, 1500 K STREET N.W., SUITE 700, WASHINGTON, DC, 20005, US

(21) Appl. No.: 11/484,778

(22) Filed: Jul. 12, 2006

Related U.S. Application Data
(60) Provisional application No. 60/698,074, filed on Jul. 12, 2005.

(51) Int. Cl. H01L 31/00

(52) U.S. Cl. 136/252

(57) ABSTRACT

A solar cell includes a semiconductor base layer, a semiconductor nanocrystal complex over the semiconductor base layer, and a semiconductor emitter layer formed over the semiconductor nanocrystal complex. The semiconductor nanocrystal complex includes nanocrystal cores dispersed in an inorganic matrix material. A corresponding method is also disclosed.

### CROSS-REFERENCE TO RELATED APPLICATIONS

The present application claims priority to U.S. Provisional Application No. 60/698,074, filed Jul. 12, 2005, which is incorporated by reference herein.

### FIELD OF THE INVENTION

The present invention relates generally to matrix materials comprising semiconductor nanocrystals and more particularly to semiconductor nanocrystal materials for use in solar cells and to methods of making solar cells comprising semiconductor nanocrystal complexes.

### BACKGROUND OF THE INVENTION

Semiconductor nanocrystals otherwise known as quantum dots are nanometer scale structures that are composed of semiconductor materials. Due to the small size of the crystals (typically, 2-10 nm), quantum confinement effects are manifest and result in size, shape, and compositionally dependent optical and electronic properties. Quantum dots have a tunable absorption onset that has increasingly large extinction coefficients at shorter wavelengths, multiple observable excitonic peaks in the absorption spectra that correspond to the quantized electron and hole states, and narrowband tunable band-edge emission spectra. Quantum dots absorb light at wavelengths shorter than the modified absorption onset and emit at the band edge.

Because they are inorganic, nanocrystals are orders of magnitude more robust than organic molecules and organic fluorophores and do not photobleach. Nanocrystals can be and often are surface modified with multiple layers of inorganic and organic coatings in order to further engineer the electronic states, control recombination mechanisms, and provide for chemical compatibility with solvent or matrix material in which the nanocrystals are dispersed.

Quantum confinement effects originate from the spatial confinement of intrinsic carriers (electrons and holes) to the physical dimensions of the material rather than to bulk length scales. One of the better-known confinement effects is the increase in semiconductor band gap energy with decreasing particle size; this manifests itself as a size dependent blue shift of the band edge absorption and luminescence emission with decreasing particle size. As nanocrystals increase in size past the exciton Bohr radius, they become electronically and optically bulk-like. Therefore nanocrystals cannot be made to have a smaller bandgap than that exhibited by the bulk materials of the same composition. By properly engineering the core and semiconductor shells in terms of size, thickness and composition, core to shell electronic transitions can be engineered that have below bandgap (of the core) emission. Such nanocrystals are referred to as Type-II nanocrystals.

Semiconductor nanocrystals have unique optical and electronic properties due to size and compositionally dependent quantized electron and hole states. The absorption spectrum is dominated by a series of overlapping peaks known as exciton peaks. Each peak corresponds to an energy state of the exciton; an electron-hole pair that is bound via coulombic forces. Aside from the first and second exciton peaks, in general, the exciton peaks increase in frequency, overlap, and strength at shorter wavelengths. Therefore the absorption coefficient generally increases at shorter wavelengths and has a bulk-like absorption profile at the short wavelength limit. The position of the first exciton peak in terms of wavelength is dependent upon the composition and size of the nanocrystals. Smaller nanocrystals will have blue shifted exciton peaks with respect to larger sized nanocrystals.

The tunable electronic band structure, small size and flexibility in device design afforded by quantum dots have great applicability to a number of energy conversion devices. These applications include photovoltaic energy conversion and thermoelectric energy conversion, in addition to their possible applicability as photocatalysts for hydrogen production, thermionic emitters, and application to fuel-cell membranes. A number of different device designs exist for photovoltaic cells alone including P-N and P-I-N single or tandem QD junctions or hot carrier cells, intermediate band solar cells, dye sensitized cells (otherwise known as Gratzel cells), a variety of luminescent and luminescent concentrator cells, and extremely thin absorber (ETA) cells.

In all of the PV applications, the control over electronic and photonic states, photostability and flexibility in device design flexibility lead to improved conversion efficiencies, possibly up to the thermodynamic limits, and reduced costs while enabling device portability and uses that require non-planar surfaces. In all the quantum dot solar cell forms, a common theme is reverberated. Namely, that tunable semiconductor materials are ideal for capturing more of the sun's light and eliminating or at least limiting the over excitation energy associated with inability to convert all the energy from high energy photons to electrical current.

Quantum dots will emit light at a wavelength slightly longer than that of the first exciton peak. That difference, the Stokes shift, is a function of the emission wavelength and composition of the nanocrystals. For example, the Stokes shift for CdSe is roughly 15 nm while PbSe is 50 nm. The emission wavelength is independent of the excitation wavelength, assuming of course that the emission wavelength is shorter than the first exciton peak (i.e. where it can be absorbed) and does not significantly overlap with the emission spectra. For example a nanocyrstal designed to emit light at 600 nm will emit at that wavelength whether excited with 350 nm or 500 nm light sources. Excitation sources near that of the emission wavelengths will only allow for a subset of the possible wavelengths to be emitted (those having a longer wavelength than the excitation source). The emission spectra is roughly Gaussian (bell shaped) and does not have the shoulders and secondary peaks exhibited by organic fluorophores.

Compared to organic dyes and fluorophores that bleach very quickly, quantum dots are over 3 orders of magnitude more photostable. The only known degradation route is through photooxidation in which singlet oxygen and oxygen radicals generated though high energy photon interactions actually etch the nanocrystals away. By dispersing nanocrystals within media with negligible oxygen diffusion rates, the nanocrysals can survive for prolonged periods of time.

Stabilizing agents are often present during growth to prevent aggregation and precipitation of the semiconductor nanocrystals. When the stabilizing molecules are attached to the nanocrystal surface as a monolayer through covalent, dative, or ionic bonds, they are referred to as capping groups. These capping groups serve to mediate nanocrystal growth, sterically stabilize nanocrystals in solution, and passivate surface electronic states in semiconductor nanocrystal. This surface capping is analogous to the binding of ligands on more traditional coordination chemistry. Synthetic organic techniques allow the tail and head groups to be independently tailored through well established chemical substitutions. Nanocrystal surface derivitization can be modified by ligand exchange: repeated exposure of the quantum dots to an excess of a competing capping group, followed by precipitation to isolate the partially exchanged nanocrystals.

Repeating this cycle allows more complete exchange. This recursive approach can cap the nanocrystals with a wide range of chemical functionalities, even if the binding of the new cap is less favorable than the original. The cap exchange process has been used extensively to adjust dimensions of the organic layer surrounding the nanocrystals and thus the minimum inter-particle spacing in NC assemblies. More often however ligand exchange procedures have been used to modify the chemical characteristics of the nanoparticle in order to make it compatible with a particular solvent or matrix. This technique has been used to make quantum dots water stabilized in a variety of ways and even stable enough for conjugation to proteins and antibodies for biological applications.

Nanocrystals grown as colloids may require organic surface capping compatible with the solvent or matrix material that they are suspended in. Polar or ionizable terminating functional groups are needed for aqueous solvents and hydrophobic groups on the terminus of the ligands are needed for compatibility with organic solvents. Polymers, silicones, sol-gel precursors or UV/thermally cured epoxies can be combined with the colloidal nanocrystals in the liquid phase provided that those precursors can dissolve in the solvent that the nanocrystals are suspended in.

Among the many contenders vying to replace fossil fuels, photovoltaic (PV) solar cells offer many advantages, including needing little maintenance and being relatively environmentally-friendly. One major drawback of PV solar cells to date has been cost. Solar radiation is a plentiful and clean source of power but due to the high cost of electrical conversion using conventional solar cells has not been exploited to its full potential when measured on a per Watt basis. The use of the semiconductor nanocrystal materials of the present invention in the various solar cell applications described should alleviate some of the drawbacks present in existing solar cells.

The semiconductor nanocrystal complexes of the present invention are ideally suited for many solar cell applications due to their ability to tune the electronic bandgap and, hence, optimize a solar cell for maximum efficiency. Furthermore, the nanocrystal complexes of the present invention may be produced in a manner that is conducive to low temperature, liquid phase processing which eliminates the need for expensive substrates and microfabrication.

To date most solar cells presently on the market are based on silicon wafers, the so-called ‘first generation’ technology. As this technology has matured, costs have become increasingly dominated by material costs, mostly those of the silicon wafer, the strengthened low-iron glass cover sheet, and those of other encapsulants. This trend is expected to continue as the photovoltaic industry continues to mature. A 1997 study of 500 MW/y production volume manufacturing showed that material costs would account for over 70% of total manufacturing costs. This necessitates more high-efficiency, high-energy conversion efficiency solar cell processing sequences, and simple, low cost manufacturing processes.

Thin film solar cells using both non-crystalline and non-silicon materials have the potential to satisfy these concerns. Because of the strong economic incentives, for the past 15 years, a switch to the ‘second generation’ of thin-film solar cell technology has occurred. Even neglecting the benefits of material costs of thin-films, thin films also offer approximately 100× increase in the size of the unit of manufacturing from a ˜100-cm2 silicon wafer to a >1 m2 glass sheet. However, non-silicon thin film solar cells have the additional challenge of achieving performance uniformity on the surface of the cell.

In short, large area, durable solar cells are required with inexpensive starting materials and inexpensive, reliable manufacturing processes. Contemporary solar cells fail on both counts. Of the naturally occurring semiconductors silicon (Si) and gallium arsenide (GaAs) are the materials best (although far from ideally) suited for the ‘first generation’, single-junction solar cell applications. Historically, crystalline silicon has been used as the light-absorbing semiconductor in most solar cells. As silicon is a relatively poor absorber of light, these cells are quite thick (˜200 to 400 μm) and use therefore a substantial amount of high-quality silicon. Despite these characteristics, Silicon has proved convenient because it yields stable solar cells with efficiencies of 11-16%.

Crystalline Si faces challenges in sustaining its pace of improvement, and despite ongoing research aimed at reducing the silicon feedstock costs, minimizing material losses, reducing energy input, and enhancing device performance, it is generally recognized that because crystalline silicon wafers make up 40-50% of the cost of a finished module, industry must address alternative technologies. It is for the reason that cheaper ‘thin film’ solar cell materials with stronger light absorption characteristics and reduced materials costs are desired. Amorphous silicon is the best developed of the ‘thin film’ technologies. Both microcrystalline Si and amorphous Si solar cells have been explored intensively in the past years. These thin film Solar cell layers, made by plasma enhanced chemical vapor deposition, are for microcrystalline Si solar cells, composed of ˜5-nm thick layers, and for —Si layers, ˜0.5 nm thick layers are used. There is a significant material reduction when compared to bulk Si solar cells, which are app 400-nm thick. This reduction of cell thickness offers three important advantages: 1) significantly reduced amount of high-quality material, 2) improved collection efficiency of electron-hole pairs, and 3) reduced sunlight-induced degradation effects in amorphous silicon cells. The latter two benefits are the result of the shorter distance the carriers have to diffuse to reach the respective contacts. However, the reduction of cell thickness also has a disadvantage: light absorption is reduced.

The semiconductor nanocrystal material of the present invention provides unique benefits in various solar cell structures. In its simplest form, the thin film Si solar cell structures have a single sequence of p-i-n layers. Such cells suffer from significant degradation in their power output (around 30% generally) when exposed to the sun. Better stability requires the use of thinner layers; however, the stability comes at the expense of reduced light absorption and cell efficiency.

As an alternative to thin film α-Si, increasingly, chalcogenide semiconductors, such as copper indium gallium diselenide (Cu(In,Ga)Se2; CIGS), cadmium sulfide (CdS) and cadmium telluride (CdTe), together with transparent conducting oxides, are the critical materials for today's leading thin-film photovoltaic (PV) technologies. Each of these is amenable to large area deposition on either coated glass or stainless sheet steel and hence is compatible with high volume manufacturing. The semiconductor heterojunctions are formed with a thin Cadmium Sulphide layer for CdTe and CIGS. The front and rear contacts are formed with a transparent conducting oxide layer, such as Indium Tin Oxide (ITO).

Despite the reduction in raw materials cost, all of the thin film technologies remain complex and expensive. For this reason the thin film solar cell technologies have taken over twenty years, supported in some cases by major corporations, to emerge from the status of promising research (about 8% efficiency) to the early low volume manufacturing facilities.

The best scenario for realizing a viable third generation technology would involve a semiconductor material(s) that could have the bandgap tuned for optimal performance and that can be manufactured with low cost. It is this opportunity that the semiconductor nanocrystal complexes of the present invention satisfy.

All of the materials introduced above, like all semiconductors, are characterized by a range of energies where charge carriers (electrons and holes) are forbidden to exist. The so-called band-gap separates the valence band (the energy band that is occupied by ground state electrons) from the conduction band (the energy band occupied by excited electrons). Semiconductors are transparent to photons having energy less than the bandgap and absorb photons greater than the bandgap by exciting an electron from the valence band to the conduction band leaving behind a positively charged hole. It is important to note that an electron excited to the conduction band by a photon having energy greater than the bandgap will lose energy as heat until the energy of the electron is reduced to the bandgap energy (also called the band edge). This loss of energy is referred to as ‘overexcitation energy (see FIG. 4). The excited state electrons and holes are free to move throughout the semiconductor. If the excited state charge carriers can be separated before they spontaneously recombine, voltage and current can be derived that can provide power to a load. Charge separation can be achieved by creating an internal electrochemical potential, typically by intentionally doping the semiconductor with impurity atoms that either lend or sequester electrons from the semiconductor host. This internal potential, referred to as a p-n junction, sweeps the free electrons to one electrode and the holes to another. The product of the output voltage and the output current determines the output power of a single junction solar cell.

### BRIEF DESCRIPTION OF THE DRAWINGS

FIG. 1 represents an example semiconductor nanocrystal complex according to an example embodiment of the present invention.

FIG. 2 represents a second example semiconductor nanocrystal complex according to a second example embodiment of the present invention.

FIG. 3 represents an example method of making an example semiconductor nanocrystal complex of the present invention.

FIG. 4 represents a TEM image of 8 nm PbSe nanocrystal colloids.

FIG. 5 represents an example Solar Cell device.

### DETAILED DESCRIPTION OF THE INVENTION

Renewable energy from the sun has great potential in reducing the dependency on fossil fuels while providing a cleaner, non-green house gas producing method for power generation. Photovoltaic (PV) devices that directly convert sunlight into electricity have found great acceptance in niche applications such as remote power for oil pipelines, monitoring stations and satellite power. Efficiency constraints associated with PV technology greatly limits its applicability as a wide scale distributed power generation source.

Thus, if one has balance of system devices (that are mostly electronic devices with high efficiencies) of near 90% efficiency, the limiting feature for overall system efficiency is the PV module efficiency. The PV module efficiency is dependent on the materials and processes used to create the module. Best in class crystalline silicon modules have materials with theoretical limits of 33% efficiency and in production as modules these devices have an efficiency of around 15% thereby making final system efficiencies in the 10-13.5% range. Alternately, successful development of advanced materials with efficiency approaching 60% that can be mass produced while minimizing the penalty on efficiency during production could result in systems with overall efficiencies in the 50-55% range yielding a four fold increase in available power for a fixed size module.

The semiconductor nanocrystal complexes of the present invention can be adapted and then implemented into PV devices through solution phase self-assembly deposition on substrates and post processing techniques. These techniques are compatible with low-cost, large area metallized polymer substrates using roll-to-roll processing.

In contrast to the limitations of contemporary solar cell technologies, semiconductor nanocrystals, in particular colloidal semiconductor nanocrystals allow for greatly increased solar cell efficiency as well as significantly decreased manufacturing costs. Because colloidal semiconductor nanocrystals can be combined with polymers in solution, most solar cell research has focused on cells comprising semiconductor nanocyrstal dispersed within conjugated polymers. Although this route can conceivably lead to low cost solar cells, the efficiency has been limited to a few tens of percent to a few percent due to difficulties in facilitating charge transport through the quantum dot/conjugated polymer interface.

The nanocrystal materials of the present invention take advantage of the potential cost savings and high efficiencies by creating MQW (multiple quantum wells)-like P-i-N structures using colloidal semiconductor nanocrystals on inexpensive substrates. Two challenges overcome by the present invention include the creation of high efficiency photovoltaic materials are minimizing thermalization losses in efficiency and maximizing charge carrier transport. The method of manufacturing the material includes; synthesizing the appropriate colloidal core/shell semiconductor nanocrystals and modifying their surfaces with volatile organic molecules, creating colloidal nanocrystal films on metallized (to facilitate better charge transport) polymer substrates through evaporation driven self-assembly processes and removing the volatile organic molecules on their surfaces through a thermal process, and fusing the outer shells of the QDs assembled on the substrate together to form a contiguous low defect film having nano-sized semiconductor complexes capable of absorbing the appropriate wavelengths of light and effectively transporting charge carriers. The preferred materials for this application are the IV-VI and III-V (PbS, PbSe, InP) based semiconductor nanocrystal cores (in the 2 nm-10 nm range) that have small bandgap of the bulk material (0.27-2.75 eV) covering the majority of the visible and near-IR spectrum.

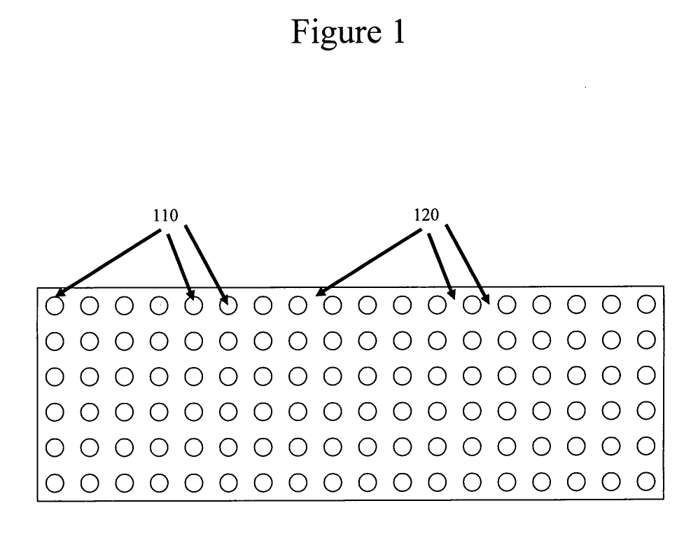

The semiconductor nanocrystal complex of the present invention comprises high efficiency photovoltaic materials that minimize losses in efficiency and maximizing charge carrier transport. FIG. 1, represents an example material of an example embodiment of the present invention. 110 represents core semiconductor nanocrystals. As discussed above, semiconductor nanocrystals are spherical nanoscale crystalline materials (although oblate and oblique spheroids and rods and other shapes may be nanocrystals) having a diameter between 1 nm and 20 nm and typically but not exclusively composed of II-VI, III-V, and IV-VI binary semiconductors. Examples of binary semiconductor materials that nanocrystals are composed of include ZnS, ZnSe, ZnTe, CdS, CdSe, CdTe, HgS, HgSe, HgTe (II-VI materials), PbS, PbSe, PbTe (IV-VI materials), AlN, AlP, AlAs, AlSb, GaN, GaP, GaAs, GaSb, InN, InP, InAs, InSb (III-V materials). In addition to binary semiconductor nanocrystals, the semiconductor nanocrystals of the present invention may be ternary semiconductor nanocrystals. Semiconductor nanocrystals materials that work particularly well for this application include IV-VI and III-V (PbS, PbSe, InP) based nano-particles (in the 2 nm-10 nm range) that have small bandgap of the bulk material (0.27-2.75 eV) covering the majority of the visible and near-IR spectrum.

120 represents an inorganic matrix material. The inorganic matrix material may be a second semiconductor material. The second semiconductor material may be any of the semiconductor nanocrystals materials discussed above. The inorganic matrix material is typically composed of a semiconductor material that has a lattice constant that matches or nearly matches the core and has a wider bulk bandgap than that of the core semiconductor.

The inorganic matrix material may have at one time been the shell around various semiconductor nanocrystal cores that was combined to form the matrix material through annealing, sintering or other process that unites the shells of the various semiconductor nanocrystals. Additionally, the inorganic matrix material may have been at one time a second population of semiconductor nanocrystals that were united to form the matrix material through annealing, sintering or other process that could unite the second population of semiconductor nanocrystals without affected the first population of semiconductor nanocrystals. Evaporation of capped semiconductor nanocrystal dispersions may produce the thin films in which the cap is weakly bound to the quantum dots. This cap can be removed, leaving a substantially inorganic superstructure. As the temperature is raised further, sintering, and grain growth occur, ultimately producing polycrystalline semiconductor nanocrystal thin films intercalated in a matrix material comprising a second semiconductor nanocrystal.

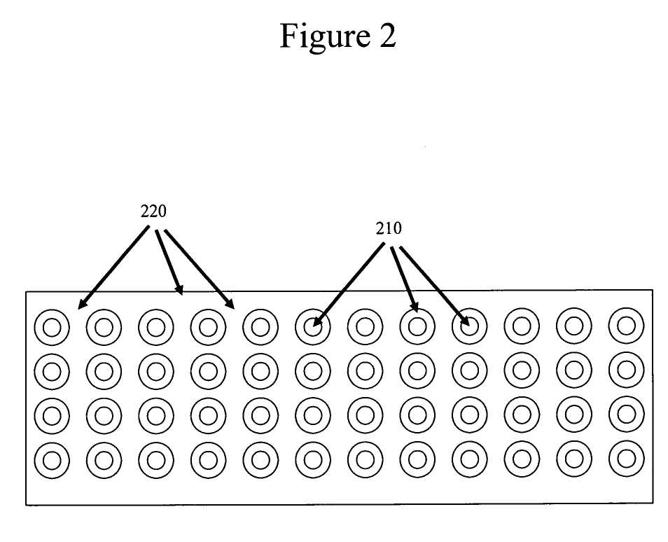

FIG. 2, represents a second material according to a second embodiment of the present invention. In this example embodiment the semiconductor nanocrystal cores 210 are core/shell semiconductor nanocrystal cores. The core semiconductor nanocrystals may be the same as those described in FIG. 1, in regard to 110. Examples of materials that may comprise the shells include CdSe, CdS, CdTe, ZnS, ZnSe, ZnTe, HgS, HgSe, HgTe, InP, InAs, InSb, InN, GaN, GaP, GaAs, GaSb, PbSe, PbS, and PbTe. The shell is typically between 0.1 nm and 10 nm thick and composed of one or more semiconductor material that has a lattice constant that matches or nearly matches the core and has a wider bulk bandgap than that of the core semiconductor.

220 represents an inorganic matrix material. The inorganic matrix material may be of a third semiconductor material. The third semiconductor material may be any of the semiconductor nanocrystals materials discussed above. The inorganic matrix material is typically composed of a semiconductor material that has a lattice constant that matches or nearly matches the core and has a wider bulk bandgap than that of the core semiconductor.

The inorganic matrix material may have at one time been the shell around various semiconductor nanocrystal core-shells that was combined to form the matrix material through annealing, sintering or other process that unites the shells of the various semiconductor nanocrystals. Evaporation of capped semiconductor nanocrystal dispersions may produce the thin films in which the cap is weakly bound to the quantum dots. This cap can be removed, leaving a substantially inorganic superstructure. As the temperature is raised further, sintering, and grain growth occur, ultimately producing polycrystalline semiconductor nanocrystal thin films intercalated in a matrix material comprising a semiconductor.

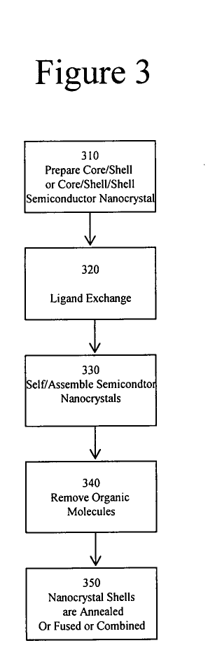

FIG. 3 represents an example method of making the semiconductor nanocrystal complex according to the present invention. In step 310, core/shell semiconductor nanocrystals are prepared in a solvent, e.g., TOPO. Preparations methods for core/shell semiconductor nanocrystals are well known in the art. In addition, core/shell semiconductor nanocrystals may be purchased from various commercial suppliers of semiconductor nanocrystals. In addition to core/shell semiconductor nanocrystals, core/shell/shell semiconductor nanocrystals may be used for the present invention. Preparations methods for core/shell/shell semiconductor nanocrystals are well known in the art. In addition, core/shell/shell semiconductor nanocrystals may be purchased from various commercial suppliers of semiconductor nanocrystals.

In step 320, the initial ligands are exchanged for pyridine ligands in solution. The solution phase synthesis results in a quantum dot colloid where each quantum dot is capped by a molecular layer of a metal chelating ligand, e.g., tri-octyl phosphine oxide (TOPO). Because TOPO is strongly bound to the nanocrystal surface, it is very difficult to drive off after the quantum dots that have been assembled into a thin film colloid crystal. Vestigial TOPO can disrupt the annealing process through which the shells of each quantum dot is combined. In order to create self assembled nanocrystal colloid crystal thin films that are free of organic impurities, pyridine or another weakly binding ligand should be substituted for the TOPO ligand or other strongly bound ligand. Although this process is described with TOPO as the initial ligand the nanocrystals are prepared and/or purchased in, there are many other strongly bonding ligands, or weakly bonding ligands, that semiconductor nanocrystals may be prepared and/or purchased in. Additionally, the semiconductor nanocrystals may be prepared directly in a weakly bonding ligand, such as pyridine. Pyridine is a weakly bound ligand that will enable the quantum dots to remain in solution before being deposited into a colloid crystal thin film and subsequently evaporated away after quantum dot deposition.

Ligand exchange can be completed in three steps: 1) the ligand the nanocrystals are prepared in (i.e., TOPO) may be removed by repeated precipitation in a centrifuge, drawing off supernatant, an adding pure solvent; 2) after the original ligand is removed, pyridine (or other suitable ligand) may be added to the nanocrystals in solvent (they will initially be a precipitate); 3) finally, the nanocrystals can be resuspended in solvent with pyridine ligands by sonication.

In step 330, the resulting semiconductor nanocrystals are self-assembled in thin films on substrates. Evaporation of pyridine-capped nanocrystal dispersions produce thin films in which the pyridine is weakly bound to the quantum dots. Tailoring the composition of the dispersing medium to provide a slow destabilization of the quantum dot dispersion as the solvent evaporates will allow for the production of three-dimensional nanocrystal superlattices. The pyridine dots are re-dispersed in a solvent, the solvent after ligand exchange. For example, the semiconductor nanocrystal with organic stabilizers, e.g. pyridine, will be induced to order in a self assembled film by evaporating a nanocrystal dispersion composed of low boiling alkane and a high boiling point alcohol. As the dispersion is concentrated, the relative concentration of the alcohol rises, slowly reducing the steric barrier to aggregation and should cause a slow separation of the nanocrystals from the dispersed state to colloid crystal state. If the rate of the transition is carefully controlled, the sticking coefficient between the nanocrystals remains low and the arrival time of the quantum dots will be such that the nanocrystals have sufficient time to find equilibrium superlattices sites on the growing structure. In the arrival limited regime, nanocrystals have enough time to diffuse at the growing surface to form ordered solids.

In step 340, the organic molecules, i.e. pyridine, are thermally driven off from the self-assembled thin film. The self-assembled thin films resulting from step 530 is gently heated under vacuum. This heating drives off the weakly bound organic molecules from the films, leaving a substantially inorganic superstructure.

In step 350, the nanocrystal complex is annealed. As the annealing temperature is raised further, sintering, and grain growth occur, ultimately producing polycrystalline semiconductor thin films intercalated with nanocrystal cores. Thus, the shell material can be annealed. This results in semiconductor nanocrystals in a matrix material wherein the matrix material comprises the shell semiconductor nanocrystal.

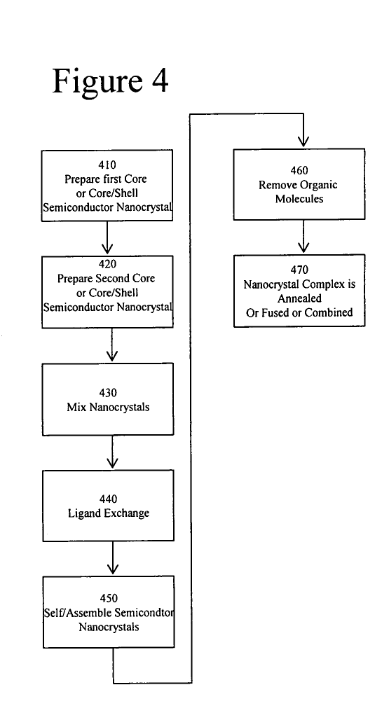

FIG. 4 represents an example method of making the semiconductor nanocrystal complex according to the present invention.

In step 410, core/shell semiconductor nanocrystals are prepared in a solvent, e.g., TOPO. Preparation methods for core/shell semiconductor nanocrystals are well known in the art. In addition, core/shell semiconductor nanocrystals may be purchased from various commercial suppliers of semiconductor nanocrystals. In addition to core/shell semiconductor nanocrystals, core semiconductor nanocrystals may be used for the present method.

In step 420, a second population of core semiconductor nanocrystals are prepared in a solvent, e.g., TOPO. Preparations methods for core semiconductor nanocrystals are well known in the art. In addition, core semiconductor nanocryatals may be purchased from various commercial suppliers of semiconductor nanocrystals. The second population of semiconductor nanocrystals should be selected such that the semiconductor nanocrystal materials have a lower melting point than the first semiconductor nanocrystal population.

In step 430, the first semiconductor nanocrystal population and the second semiconductor nanocrystal population are mixed.

In step, 440, the initial ligands for both the first population of semiconductor nanocrystals and the second population of semiconductor nanocrystals are exchanged for pyridine ligands in solution. The solution phase synthesis results in a quantum dot colloid where each quantum dot is capped by a molecular layer of a metal chelating ligand, e.g., tri-octyl phosphine oxide (TOPO). This step may be done as described in step 320 of FIG. 3.

In step 450, the resulting semiconductor nanocrystals are self-assembled in thin films on substrates. This step may be done as described in step 330 of FIG. 3.

In step 460, the organic molecules, i.e. pyridine, are thermally driven off from the self-assembled thin film. The self-assembled thin films resulting from step 630 is gently heated under vacuum. This heating drives off the weakly bound organic molecules from the films, leaving a substantially inorganic superstructure comprising the first and second population of semiconductor nanocrystals.

In step 470, the nanocrystal complex is annealed. As the annealing temperature is raised the second population of semiconductor nanocrystals should anneal around the first population of nanocrystals. The annealing temperature should be selected such that the second population of semiconductor nanocrystals will form a matrix material around the first population of semiconductor nanocrystals which should remain intact. Thus, the second population of semiconductor nanocrystals can be annealed. This results in semiconductor nanocrystals in a matrix material wherein the matrix material comprises the semiconductor of the second population of semiconductor nanocrystal.

Solar Cell

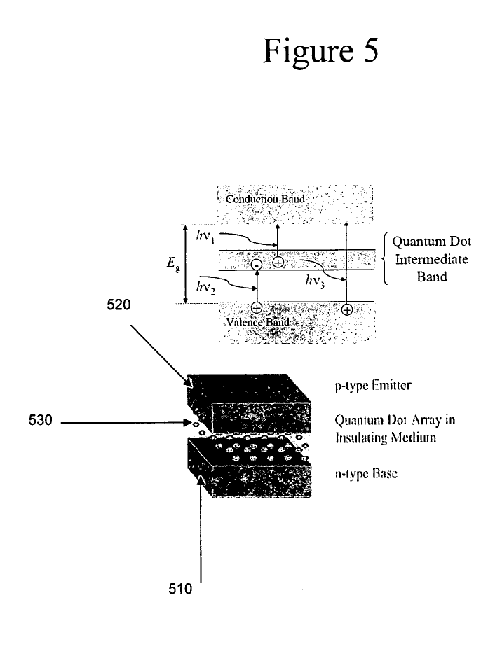

The solar cells of the present invention may be a P-I-N solar cell type structure comprising a p-type semiconductor 530, a semiconductor nanocrystal complex layer (the I layer) 520, and an n-type semiconductor 510, such as shown in FIG. 5.

The P-type semiconductor 530 contains an abundance of holes. In the case of silicon, a dopant (or acceptor) typically from group IIIA of the periodic table, such as boron or aluminium, may be substituted into the crystal silicone lattice. The dopant atom acts to accept an electron from the silicon. The loss of an electron from the silicon results in the formation of a “hole”. Each hole is associated with a nearby negative-charged dopant ion, and the semiconductor remains electrically neutral as a whole. However, once each hole has wandered away into the lattice, one proton in the atom at the hole's location will be exposed. Thus, the hole behaves as a quantity of positive charge. When a sufficiently large number of acceptor atoms are added, the holes greatly outnumber the thermally-excited electrons. Thus, the holes are the majority carriers, while electrons are the minority carriers in P-type materials.

P-type semiconductors are obtained by carrying out a process of doping, that is adding a certain type of atoms to the semiconductor in order to increase the number of free, positive charge carriers. When a doping material is added, it removes electrons from the semiconductor. This results in the doping agent being an acceptor material and the semiconductor atoms (without an electron) from holes. There are many known types of materials that may act as p-type semiconductors. The P-type semiconductor layer should be substantially transparent to light to allow it to enter the I layer.

Typically, when creating a P-I-N solar cell device an intrinsic semiconductor, also called an undoped semiconductor or i-type semiconductor, is a pure semiconductor without any significant dopant species present. The presence and type of charge carriers is therefore determined by the material itself instead of the impurities; the amount of electrons and holes is roughly equal. For the purposes of the present invention the semiconductor nanocrystal complexes, described above, may act as the i-type semiconductor in the P-I-N solar cell.

The semiconductor nanocrystal complex 530 should absorb at least a portion of the light entering the device. The semiconductor nanocrystal material may be selected such that it has an intermediate band between the band represented by the p and the n layer. Thus, as shown in FIG. 5, the intermediate layer allows for wavelengths of light that would not be able to be absorbed by just the P-layer and the N-layer. The semioconductor nanocrystal complex allows for the facilitation of charge transport by eliminating the in-organic/organic interface in polymer type semiconductor nanocrystal solar cells. The semiconductor nanocrystal complex may be constructed such that it contains more than one type of semiconductor nanocrystal core. This would allow for the absorption of more than one intermediate wavelength of light in the semiconductor nanocrystal layer.

The N-type semiconductor 510 contains an abundance of electrons. The N-type semiconductor 510 may be produced by doping, that is adding an impurity of valence five elements to the semiconductor in order to increase the number of negative charge carriers. When the doping material is added, it donates electrons to the semiconductor atoms. This type of doping agent is also known as donor material since it gives away some of its electrons. The purpose of n-type doping is to produce an abundance of mobile electrons in the material.

The semiconductor nanocrystal complexes allow for the control of the intermediate band energies since the individual quantum energy levels associated with isolated semiconductor nanocrystals is a function of their size and material composition. Placing the appropriate semiconductor nanocrystal complex 530 of the present invention within an ordinary p-i-n structure solar cell can result in the formation of accessible energy levels within what would normally be the forbidden band of the device.

The semiconductor nanocrystals complexes of the present invention can be formed into an ordered 3-D array with nanocrystal spacing sufficiently small such that strong electronic coupling occurs and minibands are formed to allow long-range electron transport (see FIG. 5). The figure represents a 3-D analog to a 1-D superlattice and the miniband structures formed therein. The delocalized quantized 3-D mini-band states could be expected to slow the carrier cooling and permit the transport and collection of hot carriers to produce a higher photopotential in a photovoltaic cell or in a photoelectrochemical cell in which the 3-D QD array is the photoelectrode.

For both mono- and poly-crystalline Si, a semiconductor homojunction is formed by diffusing an n-type dopant, typically phosphorous, into the top surface of a p-type Si wafer, typically boron doped. Screen-printed contacts are applied to the front and rear surfaces of the cell, with the front contact pattern specially designed to allow maximum light exposure of the Si material with minimum electrical (resistive) losses in the cell.

The most relevant feature of the solar cells of the present invention is the existence of an intermediate band located within what in ordinary semiconductors constitute its bandgap. The intermediate band would originate from the overlap between the electron confined-states in the dot. The electronic wave functions associated with the discrete electronic states of the quantum dots in the ordered array will overlap creating “mini-bands” within the insulating region. The materials properties (i.e., bulk bandgap, electron affinity, etc.), the size, and spacing of the quantum dots need to be chosen to produce minibands which are appropriately spaced within the bandgap of the host material. Generally speaking the lowest empty mini-band energy level should be roughly ⅓ of the bandgap energy of the semiconductor (of the n- and p-type regions) above the valence band energy to maximize the device efficiency (see FIG. 5).

This structure achieves a solar cell capable of absorbing sub-bandgap photons without degrading the output voltage of the cell. Sub-bandgap photons such as hv1 and hv2 are absorbed through electronic transitions from the valence band (VB) to the IB and from the IB to the conduction band (CB), respectively. They add up to the photocurrent produced by the absorption of a photon such as hv3 that promotes a transition from the VB to the CB.

Were they not present, the n transition layer would be equivalent to the part of the region that contains the semiconductor nanocrystal complexes in which these dots are completely filled with electrons, and the transition layer to the part in which they are completely empty of electrons. Each of these parts supports the built-in potential when the emitters are highly doped. Because the semiconductor nanocrystals would be either completely filled or completely empty with electrons in these parts, they would not play their role as intermediate band material properly (with a band half-filled with electrons). As stated earlier, their role would be purely that of supporting the built-in potential.

The semiconductor nanocrystal intermediate band solar cell is a configuration that extends the efficiency of solar cells by putting the basic operating principles of the intermediate band solar cell into practice. In general, the aim of an intermediate band solar cell architectures is to exploit the properties of the semiconductor as modified to produce an electronic (intermediate) band that splits the original (single) gap into two sub-gaps. Photons with energies, hf, less than the fundamental gap Eg of the unmodified semiconductor are absorbed via transitions involving this intermediate band (IB) to create extra free charges that contribute to an enhanced photocurrent from the cell.

1. A solar cell comprising:
a semiconductor base layer;
a semiconductor nanocrystal complex over the semiconductor base layer; and
a semiconductor emitter layer formed over the semiconductor nanocrystal complex, wherein the semiconductor nanocrystal complex comprises nanocrystal cores dispersed in an inorganic matrix material.

2. The solar cell of claim 1, wherein the semiconductor nanocrystal cores further comprise shells formed around each of the semiconductor nanocrystal cores.

3. The solar cell of claim 1, wherein the semiconductor base layer is an n-type base layer and the semiconductor emitter layer is a p-type emitter layer.

4. The solar cell of claim 2, wherein the material properties of the semiconductor nanocrystal cores are selected to produce a desired intermediate energy bandgap.

5. The solar cell of claim 4, wherein the material properties of the semiconductor nanocrystal cores is selected to produce energy minibands within a bandgap of the semiconductor base layer and the semiconductor emitter layer.

6. The solar cell of claim 5, wherein the material properties comprise at least one of a spacing of the semiconductor nanocrystal cores, a size of the semiconductor nanocrystal cores, and electronic properties of the semiconductor nanocrystal cores.

7. The solar cell of claim 5, wherein a lowest of the energy minibands has a miniband energy level approximately ⅓ of a bandgap energy of the semiconductor base layer and the semiconductor emitter layer.

8. The solar cell of claim 1, wherein the semiconductor nanocrystal complex comprises two populations of semiconductor nanocrystals having different properties.

9. The solar cell of claim 1, wherein the inorganic material comprises a semiconductor material.

10. A method of forming a solar cell, comprising:
forming a semiconductor base layer;
forming a semiconductor nanocrystal complex over the semiconductor base layer; and
forming a semiconductor emitter layer over the semiconductor nanocrystal complex, wherein forming the semiconductor nanocrystal complex comprises forming nanocrystal cores dispersed in an inorganic matrix material.

11. The method of claim 10, wherein forming the semiconductor nanocrystal cores further comprises forming formed around each of the semiconductor nanocrystal cores.

12. The method of claim 10, wherein forming the semiconductor base layer comprises forming an n-type base layer and forming the semiconductor emitter layer comprises forming a p-type emitter layer.

13. The method of claim 11, further comprising selecting the material properties of the semiconductor nanocrystal cores to produce a desired intermediate energy bandgap.

14. The method of claim 13, further comprising selecting the material properties of the semiconductor nanocrystal cores to produce energy minibands within a bandgap of the semiconductor base layer and the semiconductor emitter layer.

15. The method of claim 14, wherein the material properties comprise at least one of a spacing of the semiconductor nanocrystal cores, a size of the semiconductor nanocrystal cores, and electronic properties of the semiconductor nanocrystal cores.

16. The method of claim 14, wherein a lowest of the energy minibands has a miniband energy level approximately ⅓ of a bandgap energy of the semiconductor base layer and the semiconductor emitter layer.

17. The method of claim 10, wherein the semiconductor nanocrystal complex comprises two populations of semiconductor nanocrystals having different properties.

18. The method of claim 10, wherein the inorganic material comprises a semiconductor material.
